(19) United States
(12) Patent Application Publication
(10) Pub. No.: US 2026/0286256 A1
(43) Pub. Date: Sep. 24, 2026

(54) SURFACE TREATMENT AGENT, SILICON COMPOUND, AND METHOD FOR SUPPRESSING PATTERN COLLAPSE WHEN SUBSTRATE SURFACE IS CLEANED WITH CLEANING LIQUID

(71) Applicant: TOKYO OHKA KOGYO CO., LTD., Kanagawa (JP)

(72) Inventor: Akira MATSUYAMA, Kanagawa (JP)

(21) Appl. No.: 19/561,839

(22) Filed: Mar. 10, 2026

Related U.S. Application Data
(60) Provisional application No. 63/775,520, filed on Mar. 21, 2025.

(51) Int. Cl. C11D 7/32; C07F 7/18; H10P 70/00

(52) U.S. Cl. CPC C11D 7/3209; C07F 7/1872; H10P 70/23; C11D 2111/22

(57) ABSTRACT

To provide a surface treatment agent capable of satisfactorily providing a surface of a substrate with liquid repellency, a silicon compound capable of being suitably included in the surface treatment agent, and a method for suppressing pattern collapse using the surface treatment agent when the substrate surface is cleaned with a cleaning liquid. In a surface treatment agent used for treating a surface of a substrate having a pattern, and containing a reactive silane compound, and a solvent including water, by using a reactive silane compound, including a nitrogen atom-containing group including a bonding represented by >C═N—(C₁-C₅ alkylene group)- as the reactive silane compound, it has been found that the above-mentioned problems can be solved, and the present invention has been completed. More specifically, the present invention provides the following.

This application is based on and claims the benefit of priority from U.S. Patent Application No. U.S. 63/775,520, filed on 21 Mar. 2025, the content of which is incorporated herein by reference.

### BACKGROUND OF THE INVENTION

### Field of the Invention

The present invention relates to a surface treatment agent, a silicon compound, and a method for suppressing pattern collapse when a substrate surface is cleaned with a cleaning liquid.

### Related Art

In manufacturing of a semiconductor device and the like, a lithography technique is used before subjecting a substrate to treatment such as etching. In this lithography technique, a photosensitive resin layer is provided on the substrate using a photosensitive resin composition, then is exposed by selective irradiation with active radiation, and is subjected to developing treatment, followed by selectively dissolving and removing the photosensitive resin layer so as to form an organic pattern on the substrate. Then, by carrying out etching treatment using the organic pattern as a mask, an inorganic pattern is formed on the substrate.

In recent years, semiconductor devices have been increasingly highly integrated and miniaturized, and inorganic patterns on the substrate have become finer and have had higher aspect ratio. On the other hand, however, a problem of so-called pattern collapse has occurred. The pattern collapse is a phenomenon in which when a large number of inorganic patterns are formed in parallel on a substrate, adjacent patterns are close so as to lean on each other, and the patterns may be broken and peeled from a base depending on the situation. Occurrence of such pattern collapse causes decrease in yield and reliability of products.

The pattern collapse is known to occur due to surface tension of a cleaning liquid when the cleaning liquid is dried in cleaning treatment after pattern formation. In other words, when the cleaning liquid is removed in the drying process, stress based on the surface tension of the cleaning liquid acts between the patterns so that pattern collapse occurs.

Thus, many trials have been made so far to prevent pattern collapse by adding a substance for reducing the surface tension to the cleaning liquid. For example, a cleaning liquid to which isopropyl alcohol is added, a cleaning liquid to which a fluorine-based surface-active agent is added, and the like, have been proposed (see, for example, Patent Document 1).
Patent Document 1: Japanese Unexamined Patent Application, Publication No. H6-163391

### SUMMARY OF THE INVENTION

However, a cleaning liquid devised as described in Patent Document 1 is not enough to prevent pattern collapse.

Here, examples of the method for preventing pattern collapse include a method of providing a pattern surface with water repellency, and increasing a contact angle of a cleaning liquid, in addition to a method of reducing surface tension of a cleaning liquid. When the pattern on the substrate is cleaned with the cleaning liquid, force F acting between the patterns is represented by the following formula (a). Herein, y represents surface tension of a cleaning liquid, 0 represents a contact angle of the cleaning liquid, A represents an aspect ratio of a pattern, and D represents a distance between pattern side walls.

$$F = 2 γ \cdot cos θ \cdot A / D \qquad ( a )$$

Therefore, when the surface of the pattern can be provided with water repellency, and the contact angle of the cleaning liquid can be increased (cos θ can be reduced), force acting between the patterns in the subsequent cleaning can be reduced, and pattern collapse can be prevented.

The present invention has been made in view of such points, and has an object to provide a surface treatment agent capable of satisfactorily providing a surface of a substrate with liquid repellency, a silicon compound capable of being suitably included in the surface treatment agent, and a method for suppressing pattern collapse using the surface treatment agent when a substrate surface is cleaned with a cleaning liquid.

The present inventors have extensively studied, and as a result found that the above-mentioned problems can be solved by using a reactive silane compound in a surface treatment agent for use in treating a surface of a substrate having a pattern, and containing a reactive silane compound, and a solvent including water, wherein the reactive silane compound includes a nitrogen atom-containing group including a bonding represented by >C═N—(C₁-C₅ alkylene group)-, and has completed the present invention. More specifically, the present invention provides the following. A surface treatment agent including a reactive silane compound and a solvent, the reactive silane compound including a compound represented by the following formula (1):

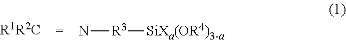

wherein in the formula (1), R¹ and R² are each independently a monovalent hydrocarbon group having 1 or more and 15 or less carbon atoms, optionally having a substituent, or a hydrogen atom, R¹ and R² are not simultaneously a hydrogen atom, R¹ and R² are optionally bonded to each other to form a hydrocarbon ring, a total number of carbon atoms of R¹ and R² is 2 or more and 20 or less, R³ is an alkylene group having 1 or more and 5 or less carbon atoms, R⁴ is an alkyl group having 1 or more and 4 or less carbon atoms, or a hydrogen atom, X is a hydrocarbon group having 1 or more and 6 or less carbon atoms, and a is an integer of 0 or more and 2 or less, and the solvent including water.

A second embodiment of the present invention is a silicon compound represented by the following formula (2):

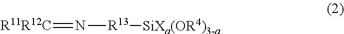

(In the formula (2), R¹¹ and R¹² are each independently a monovalent hydrocarbon group having 1 or more and 15 or less carbon atoms, optionally having a substituent, or a hydrogen atom, both R¹¹ and R¹² are not simultaneously a hydrogen atom, R¹¹ and R¹² are optionally bonded to each other to form a hydrocarbon ring, a total number of carbon atoms of R¹¹ and R¹² is 2 or more and 20 or less, R¹³ is an alkylene group having 1 or more and 5 or less carbon atoms, R¹⁴ is an alkyl group having 1 or more and 4 or less carbon atoms, or a hydrogen atom, X is a hydrocarbon group having 1 or more and 6 or less carbon atoms, a is an integer of 0 or more and 2 or less, and when one of R¹¹ and R¹² is an n-propyl group, an isopropyl group, or a tert-butyl group, the other of R¹¹ and R¹² is not a hydrogen atom).

A third embodiment of the present invention is a method for suppressing pattern collapse in a substrate including a pattern on a surface thereof when the surface of the substrate is cleaned with a cleaning liquid, the method including bringing the surface treatment agent according to the first embodiment into contact with the surface of the substrate.

The present invention can provide a surface treatment agent capable of satisfactorily providing a surface of a substrate with liquid repellency, a silicon compound capable of being suitably included in the surface treatment agent, and a method for suppressing pattern collapse using the surface treatment agent when a substrate surface is cleaned with a cleaning liquid.

### DETAILED DESCRIPTION OF THE INVENTION

### [Surface Treatment Agent]

A surface treatment agent is used for treating a surface of a substrate having a pattern. The surface treatment agent includes a reactive silane compound and a solvent. The reactive silane compound includes a compound represented by the formula (1) mentioned later. The solvent includes water. By carrying out surface treatment of a substrate surface using such a surface treatment agent, a surface of a substrate having a pattern can be satisfactorily provided with water repellency. As a result, pattern collapse can be suppressed when the surface of the substrate having a pattern is cleaned with a cleaning liquid. Hereinafter, each component capable of being included in the surface treatment agent is described.

### (Reactive Silane Compound)

The surface treatment agent includes a reactive silane compound. The reactive silane compound includes a compound represented by the following formula (1).

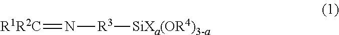

In the formula (1), R¹ and R² are each independently a monovalent hydrocarbon group having 1 or more and 15 or less carbon atoms, optionally having a substituent, or a hydrogen atom. R¹ and R² are not simultaneously a hydrogen atom. R¹ and R² may be bonded to each other to form a hydrocarbon ring. A total number of carbon atoms of R¹ and R² is 2 or more and 20 or less. R³ is an alkylene group having 1 or more and 5 or less carbon atoms. R⁴ is an alkyl group having 1 or more and 4 or less carbon atoms, or a hydrogen atom. X is a hydrocarbon group having 1 or more and 6 or less carbon atoms. a is an integer of 0 or more and 2 or less.

R¹ and R² in the formula (1) are each independently a monovalent hydrocarbon group having 1 or more and 15 or less carbon atoms, optionally having a substituent, or a hydrogen atom. The number of carbon atoms of the monovalent hydrocarbon group as R¹ and R² is preferably 2 or more and 15 or less. As long as the desired effect is not impaired, the monovalent hydrocarbon group as R¹ and R² may include a substituent. Examples of the substituent include a carboxy group, a hydroxy group, an amino group, a halogen atom, an alkoxy group, an alkoxycarbonyl group, and the like.

The monovalent hydrocarbon group may be an aliphatic hydrocarbon group or an aromatic hydrocarbon group, or a combination of an aliphatic hydrocarbon group and an aromatic hydrocarbon group. Examples of the monovalent hydrocarbon groups include linear or branched alkyl groups, linear or branched alkenyl groups, and cyclic hydrocarbon groups.

The number of carbon atoms of the linear alkyl group is 1 or more and 15 or less, preferably 2 or more and 13 or less, and more preferably 2 or more and 11 or less. Specific examples of the linear alkyl groups include a methyl group, an ethyl group, an n-propyl group, an n-butyl group, an n-pentyl group, an n-hexyl group, an n-heptyl group, an n-octyl group, an n-nonyl group, an n-decyl group, an n-undecyl group, an n-dodecyl group, an n-tridecyl group, an n-tetradecyl group, and an n-pentadecyl group.

The number of carbon atoms of the branched alkyl group is 3 or more and 15 or less, preferably 3 or more and 8 or less, and more preferably 3 or more and 5 or less. Examples of the branched alkyl groups include an isopropyl group, an isobutyl group, a sec-butyl group, a tert-butyl group, an isopentyl group, a neopentyl group, a 2-ethylhexyl group, and the like.

The number of carbon atoms of the linear alkenyl group is 2 or more and 15 or less, preferably 2 or more and 13 or less, and more preferably 2 or more and 11 or less. Examples of the linear alkenyl groups include a vinyl group, a 1-propenyl group, a 2-propenyl group (an allyl group), a 1-butenyl group, a 2-butenyl group, a 3-butenyl group, a 4-pentenyl group, a 5-hexenyl group, a 6-heptenyl group, a 7-octenyl group, a 8-nonenyl group, a 9-decenyl group, a 10-undecenyl group, a 11-dodecenyl group, a 12-tridecenyl group, a 13-tetradecenyl group, a 14-pentadecenyl group, and the like. Examples of the branched alkenyl groups include a 1-methylvinyl group, a 1-methyl-1-propenyl group, a 1-methyl-2-propenyl group, a 2-methyl-1-propenyl group, a 2-methyl-2-propenyl group, and the like.

The cyclic hydrocarbon group may be a monocyclic group or a polycyclic group. Note here that the polycyclic group is a group in which two or more monocyclic hydrocarbon groups condense to each other, or are bonded to each other via a single bond. The cyclic hydrocarbon group may be an aromatic hydrocarbon group, or may be an alicyclic hydrocarbon group. When the cyclic hydrocarbon group is a polycyclic group, two or more hydrocarbon rings included in the hydrocarbon group may be an aliphatic hydrocarbon group, or an aromatic hydrocarbon group, a combination of an aliphatic hydrocarbon ring and an aromatic hydrocarbon ring.

The aliphatic hydrocarbon group as a monocyclic group is preferably a group obtained by removing one hydrogen atom from monocycloalkane. The number of carbon atoms of the monocycloalkane is preferably 3 or more and 10 or less, more preferably 4 or more and 8 or less, and further preferably 5, or 6. Specific examples of the monocycloalkane include cyclopropane, cyclobutane, cyclopentane, cyclohexane, cycloheptane, cyclooctane, cyclononane, and the like. The group obtained by removing one hydrogen atom from the monocycloalkane is preferably a cyclopentyl group and a cyclohexyl group.

Furthermore, the aliphatic hydrocarbon group as the polycyclic group is preferably a group obtained by removing one hydrogen atom from polycycloalkane. The number of carbon atoms of the polycycloalkane is preferably 7 or more and 10 or less. Specific examples of the polycycloalkane include adamantane, norbornane, and the like.

Examples of the aromatic hydrocarbon group include a phenyl group, a naphthalene-1-yl group, a naphthalene-2-yl group, a 2-phenylphenyl group, a 3-phenylphenyl group, a 4-phenylphenyl group, and the like.

R¹ and R² may be bonded to each other to form a hydrocarbon ring. The hydrocarbon ring formed by bonding R¹ and R² to each other may be a monocyclic group or a polycyclic group. Herein, the compound represented by the formula (1) has a structure represented by R¹R²C═N—. Therefore, a hydrocarbon ring formed by bonding R¹ and R² to each other is a monocyclic or polycyclic aliphatic hydrocarbon ring, or is polycyclic in which another hydrocarbon ring or an aromatic hydrocarbon ring is condensed to the aliphatic hydrocarbon ring.

The combination of R¹ and R² preferably includes a hydrocarbon group as R¹ and a hydrogen atom as R². In this case, from the viewpoint that the surface of the substrate can be satisfactorily provided with liquid repellency, the hydrocarbon group as R¹ is preferably a linear alkyl group having 6 or more and 15 or less carbon atoms, and a branched alkyl group having 4 or more and 15 or less carbon atoms, and more preferably a linear alkyl group having 7 or more and 12 or less carbon atoms, and a branched alkyl group having 4 or more and 12 or less carbon atoms.

R³ in the formula (1) is an alkylene group having 1 or more and 5 or less carbon atoms. Examples of the alkylene group include a methylene group, an ethylene group (an ethane-1,2-diyl group), a propane-1,2-diyl group, a propane-1,3-diyl group, a butane-1,4-diyl group, and a pentane-1,5-diyl group. Among these, a methylene group, an ethylene group (an ethane-1,2-diyl group), and a propane-1,3-diyl group are preferable, and a propane-1,3-diyl group is more preferable.

R⁴ in the formula (1) is an alkyl group having 1 or more and 4 or less carbon atoms, or a hydrogen atom. As R⁴, a methyl group and an ethyl group are preferable. Examples of the alkyl group include a methyl group, an ethyl group, an n-propyl group, an isopropyl group, an n-butyl group, an isobutyl group, a sec-butyl group, and a tert-butyl group. As described later, when a is 0 or 1, a plurality of R⁴s may be the same as each other, or different from each other, and are preferably the same as each other.

X in the formula (1) is a hydrocarbon group having 1 or more and 6 or less carbon atoms. The number of carbon atoms of the hydrocarbon group as X is preferably 1 or more and 4 or less. Examples of the hydrocarbon group having 1 or more and 6 or less carbon atoms include a linear or branched alkyl group, a linear or branched alkenyl group, and a cyclic hydrocarbon group. Suitable specific examples of the hydrocarbon group as X include alkyl groups such as a methyl group, an ethyl group, an n-propyl group, an isopropyl group, an n-butyl group, an isobutyl group, a sec-butyl group, a tert-butyl group, an n-pentyl group, and an n-hexyl group, alkenyl groups such as a vinyl group, a 2-propenyl group (an allyl group), a 1-propenyl group, a 3-butenyl group, a 4-pentenyl group, and a 5-hexenyl group, a cyclopropyl group, a cyclobutyl group, a cyclopentyl group, and a cyclohexyl group, and a phenyl group. Among these, a methyl group and an ethyl group are preferable, and a methyl group is more preferable. When a described below is 2, two Xs may be the same as each other, or different from each other, and are preferably the same as each other.

a in the formula (1) is an integer of 0 or more and 2 or less, and 0 is preferable.

Examples of the reactive silane compound represented by the formula (1) include compounds represented by the following formulae (a) to (i). In the following formula, OEt is an ethoxy group. Furthermore, in the following structures, a compound having a structure in which a triethoxysilyl group is changed to a trimethoxysilyl group, and a compound in which a propane 1,3-diyl group is changed to an ethylene group (ethane-1,2-diyl group) or a butane-1,4-diyl group are also preferable as the compound represented by the formula (1).

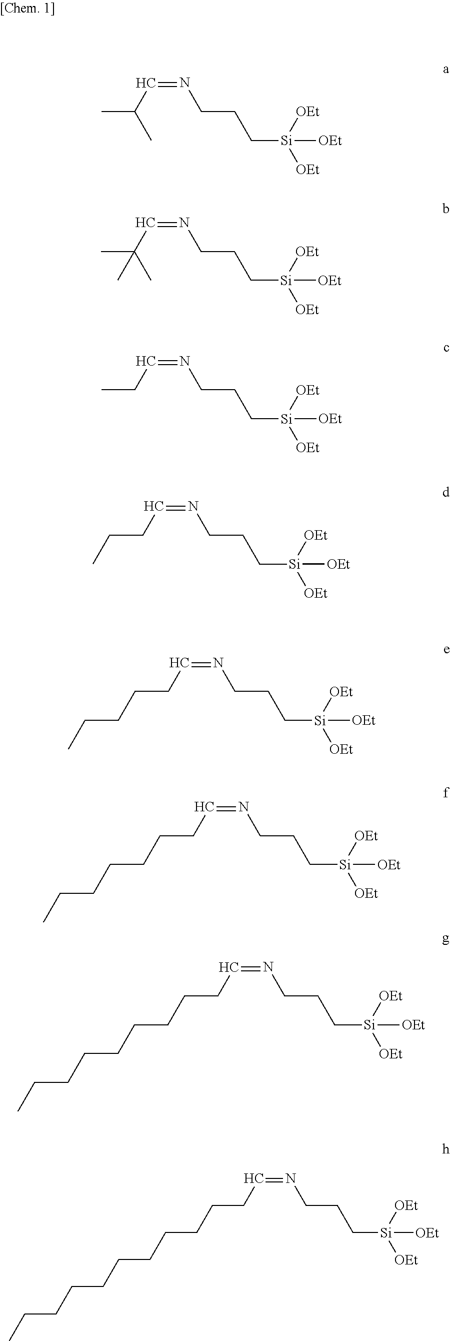

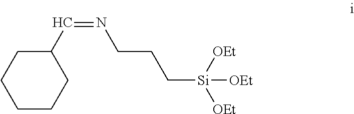 [SMILES: CCO[Si](CCC/N=C\C1CCCCC1)(OCC)OCC]

Note here that the reactive silane compound may be used alone or in combination of two or more compounds.

The content of the reactive silane compound in the surface treatment agent is not particularly limited as long as the desired effect is not impaired. The content of the reactive silane compound is preferably 0.01% by mass or more and 10% by mass or less, more preferably 0.05% by mass or more and 5% by mass or less, and further preferably 0.1% by mass or more and 3% by mass or less with respect to the mass of the surface treatment agent.

The reactive silane compound may include various well-known reactive silane compounds as a water-repelling agent together with the compound represented by the formula (1). Examples of the well-known reactive silane compounds other than the compounds represented by the formula (1) include various alkoxysilanes that do not correspond to the compound represented by the formula (1). A rate of the mass of the compound represented by the formula (1) with respect to the mass of the reactive silane compound is preferably 50% by mass or more, more preferably 70% by mass or more, further preferably 80% by mass or more, particularly preferably 90% by mass or more, and the most preferably 100% by mass.

### (Solvent)

The surface treatment agent includes a solvent. The solvent includes water. A rate of the mass of the solvent with respect to the mass of the surface treatment agent is not particularly limited. A rate of the mass of the solvent with respect to the mass of the surface treatment agent is appropriately determined in consideration of the amount of the reactive silane compound in the surface treatment agent and the amount of the other additives mentioned later. Typically, the surface treatment agent includes only a reactive silane compound and a solvent. In this case, a value of the rate of the solvent with respect to the mass of the surface treatment agent is a value obtained by subtracting the rate of the mass of the reactive silane compound with respect to the mass of the surface treatment agent from 100% by mass.

The rate of the mass of water with respect to the mass of the solvent is not particularly limited. The rate of the mass of water with respect to the mass of the solvent is preferably 20% by mass or more and 100% by mass or less, more preferably 50% by mass or more and 100% by mass or less, and further preferably 80% by mass or more and 100% by mass or less.

Furthermore, from the viewpoint that surface treatment of a substrate by, for example, an immersion method and a spin-coating method is easy, the surface treatment agent may include an organic solvent together with water as the solvent. The organic solvent is not particularly limited as long as it can be uniformly mixed with a desired amount of water and the surface of a treatment target is not damaged or is little damaged when the surface treatment is carried out using a surface treatment agent. Note here that the surface of the treatment target is, for example, a surface of a substrate having an inorganic pattern, an organic pattern, or the like. As the organic solvent, for example, a conventionally known water-soluble organic solvent can be used. The “water-soluble” herein refers to as a property in which 0.5 g or more solutes are dissolved in 100 g of water at 25° C.

Examples of the water-soluble organic solvent include an ether-based solvent, a ketone-based solvent, an alcohol-based solvent, a nitrogen-containing polar organic solvent, dimethyl sulfoxide, hexamethylphosphoric triamide, acetonitrile, and the like. Note here that in the specification and the claims of the present application, compounds corresponding to ketones and ethers having an alcoholic hydroxyl group are classified as alcoholic-based solvents. Furthermore, compounds corresponding to both ketone and ether are classified as a ketone-based solvent.

Examples of the ether-based solvent as the water-soluble organic solvent include tetrahydrofuran (THF), dioxane, trioxane, 1,2-dimethoxyethane, diethylene glycol dimethyl ether, diethylene glycol diethyl ether, and the like.

Examples of the ketone-based solvent as the water-soluble organic solvent include acetone, methyl ethyl ketone, cyclohexanone, and the like.

Examples of the alcohol-based solvent as the water-soluble organic solvent include methanol, ethanol, 1-propanol, 2-propanol, tert-butyl alcohol, ethylene glycol, ethylene glycol monomethyl ether, ethylene glycol monoethyl ether, diethylene glycol, diethylene glycol monomethyl ether, diethylene glycol monoethyl ether, 1,2-propanediol, 1,3-propanediol, 1,3-butanediol, 1,4-butanediol, 2,3-butanediol, 1,5-pentanediol, 2-butene-1,4-diol, 2-methyl-2,4-pentanediol, glycerin, 2-ethyl-2-hydroxymethyl-1,3-propanediol, 1,2,6-hexanetriol, and the like.

Examples of the nitrogen-containing polar organic solvent as the water-soluble organic solvent include N-methyl-2-pyrrolidone (NMP), N, N-dimethylacetamide (DMAc), N,N-dimethylisobutylamide, N, N-diethylacetamide, N, N-dimethylformamide (DMF), N, N-diethylformamide, N-methylcaprolactam, 1,3-dimethyl-2-imidazolidinone (DMI), pyridine, N, N,N′,N′-tetramethylurea (TMU), and the like.

These water-soluble organic solvents may be used alone or in combination of two or more solvents.

### (Other Additives)

The surface treatment agent may include other additives other than the reactive silane compound and the above-mentioned solvent as long as the desired effect is not impaired. Other kinds of additives are not particularly limited as long as the desired effect is not impaired. Specific examples of the other additives include a surface-active agent, a defoaming agent, a pH adjusting agent, and the like.

### [Silicon Compound]

As a new silicon compound, a compound represented by the following formula (2) is provided.

R¹¹R¹²C═N—R³—SiXₐ(OR⁴)₃₋ₐ (2)

In the formula (2), R¹¹ and R¹² are each independently a monovalent hydrocarbon group having 1 or more and 15 or less carbon atoms, optionally having a substituent, or a hydrogen atom. R¹¹ and R¹² are not simultaneously a hydrogen atom. R¹¹ and R¹² may be bonded to each other to form a hydrocarbon ring. The total number of carbon atoms of R¹¹ and R¹² is 2 or more and 20 or less. R³ is an alkylene group having 1 or more and 5 or less carbon atoms. R⁴ is an alkyl group having 1 or more and 4 or less carbon atoms, or a hydrogen atom. X is a hydrocarbon group having 1 or more and 6 or less carbon atoms. a is an integer of 0 or more 2 or less. Herein, when one of R¹¹ and R¹² is an n-propyl group, an isopropyl group, or a tert-butyl group, the other of R¹¹ and R¹² is not a hydrogen atom.

In the formula (2), R¹¹ is the same as R¹ in the formula (1) and R¹² is the same as R² in the formula (1) except that when one of R¹¹ and R¹² is an n-propyl group, an isopropyl group, or a tert-butyl group, the other of R¹¹ and R¹² is not a hydrogen atom.

In the formula (2), the combination of R¹¹ and R¹² is preferably a combination of R¹¹ that is an ethyl group, a linear alkyl group having 4 or more and 15 or less carbon atoms, a branched alkyl group having 5 or more and 15 or less carbon atoms, or an alicyclic hydrocarbon group having 3 or more and 15 or less carbon atoms, and R¹² that is a hydrogen atom.

From the viewpoint that the surface of the substrate can be satisfactorily provided with liquid repellency, the hydrocarbon group as R¹¹ is preferably a linear alkyl group having 6 or more and 15 or less carbon atoms, and a branched alkyl group having 5 or more and 15 or less carbon atoms are preferable, and a linear alkyl group having 7 or more and 12 or less carbon atoms, and a branched alkyl group having 5 or more and 12 or less carbon atoms are more preferable.

R³, R⁴, X, and a in the formula (2) are the same as R³, R⁴, X, and a in the formula (1).

Suitable examples of the compound represented by the formula (2) include the following compounds. In the following formula, OEt is an ethoxy group. In the following structure, a compound having a structure in which a triethoxysilyl group is changed to a trimethoxysilyl group, and a compound in which a propane 1,3-diyl group is changed to an ethylene group (an ethane-1,2-diyl group) or a butane-1,4-diyl group are also preferable as the compound represented by the formula (1).

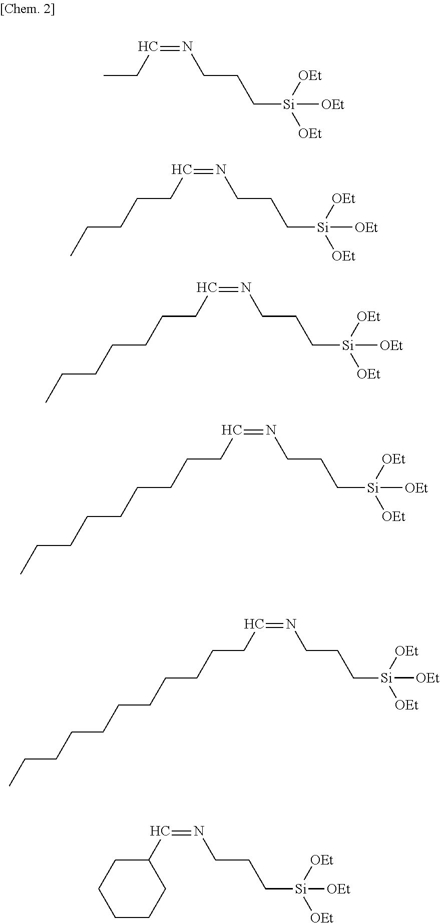 [SMILES: CC/C=N\CCC[Si](OCC)(OCC)OCC ; CCCCC/C=N\CCC[Si](OCC)(OCC)OCC ; CCCCCCC/C=N\CCC[Si](OCC)(OCC)OCC ; CCCCCCCCC/C=N\CCC[Si](OCC)(OCC)OCC ; CCCCCCCCCCC/C=N\CCC[Si](OCC)(OCC)OCC ; CCO[Si](CCC/N=C\C1CCCCC1)(OCC)OCC]

A method for manufacturing a compound represented by the formula (2) is not particularly limited. For example, the compound represented by the formula (2) can be manufactured by subjecting an aldehyde or a ketone represented by formula (2-1) and an aminosilane compound represented by the formula (2-2) to an imine formation reaction in which an aldehyde or a ketone is dehydrated and condensed with a primary amine according to a common method. In the following formula (2-1) and the formula (2-2), R¹¹, R¹², R³, R⁴, X, and a are the same as those in the formula (2).

R¹¹R¹²C═O (2-1)

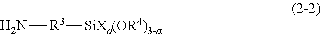

The reaction of the aldehyde or the ketone represented by the formula (2-1) with the aminosilane compound represented by the formula (2-2) is usually carried out in an organic solvent such as ethyl acetate, toluene, and xylene, being inert to the imine formation reaction. The ratio M1:M2 of the number of moles M1 of the aldehyde or ketone represented by the formula (2-1) to the number of moles M2 of the aminosilane compound represented by the formula (2-2) in the above reaction is preferably from 0.8:1 to 1:0.8, more preferably from 0.9:1 to 1:0.9, and particularly preferably 1:1. The aldehyde or the ketone represented by the formula (2-1) may be reacted with an aminosilane compound represented by the formula (2-2) in the presence of a catalytic amount of acid for the purpose of accelerating the reaction.

### [Method for Suppressing Pattern Collapse]

A method for suppressing pattern collapse is a method for suppressing pattern collapse when a surface of the substrate is cleaned with a cleaning liquid, in the substrate having a pattern on the surface thereof.

### (Substrate)

A substrate is not particularly limited as long as the substrate has a pattern on a surface thereof. Examples of the substrate include a substrate to be used for producing a semiconductor device. Furthermore, examples of the surface of the substrate include a surface of the substrate itself, a surface of a patten provided on the substrate, and surfaces of unpatterned inorganic and organic layers. The pattern provided on the substrate may be an organic pattern made of organic material, or an inorganic pattern made of inorganic material.

At least a part of the substrate surface to be surface-treated preferably includes one or more kinds selected from silicon, silicon dioxide, and silicon nitride.

From the viewpoint of suppressing collapse of an organic pattern or an inorganic pattern when the surface of the substrate is cleaned with a cleaning liquid, a substrate preferably includes an organic pattern or an inorganic pattern on a surface with which the surface treatment agent is brought into contact.

Examples of the organic pattern provided on the substrate include a resin pattern formed on the substrate by a photolithography method using a photoresist or the like. Such an organic pattern can be formed, for example, by forming an organic layer, which is a film of photoresist, on a substrate, exposing the organic layer through a photomask, and developing the organic layer. The organic layer may be formed not only on the surface of the substrate itself but also on the surface of a laminated film formed on the surface of the substrate. Such an organic layer is not particularly limited, but includes an organic film provided for forming an etching mask in the process of producing a semiconductor device.

Examples of the inorganic pattern provided on the substrate include a pattern formed by producing an etching mask on the surface of an inorganic layer existing on the substrate by a photoresist method and then carrying out an etching treatment. Examples of the inorganic layer include, an oxide film of an element constituting the substrate, and a film or layer of an inorganic substance such as silicon and silicon nitride formed on the surface of the substrate, in addition to the substrate itself. Furthermore, examples of such a film or a layer is not particularly limited and include a film or a layer of inorganic substance formed in production process of the semiconductor device.

Examples of the method for bringing the surface treatment agent into contact with the surface of the substrate include a method of applying (for example, coating) the surface treatment agent to the surface of the substrate by an immersion method, a spin coating method, or the like, and bringing the surface treatment agent into contact with the surface of the substrate.

A temperature of the surface treatment agent that is brought into contact with the surface of the substrate is preferably 10° C. or more and 90° C. or less, more preferably 20° C. or more and 80° C. or less, further preferably 30° C. or more and 70° C. or less, and particularly preferably 40° C. or more and 60° C. or less. Furthermore, time during which the surface of the substrate and the surface treatment agent are in contact with each other is preferably 15 seconds or more and 30 minutes or less, and more preferably 30 seconds or more and 10 minutes or less from the viewpoint of water repellency (for example, a contact angle with respect to water). Cleaning (for example, cleaning with water, an active agent rinse, and the like) and/or drying (drying by nitrogen blowing) may be carried out after film formation if necessary. Furthermore, to the treated substrate after drying, heating treatment at 100° C. or more and 300° C. or less may be added if necessary.

The above contact allows the above-described reactive silicon compound to be bonded to the surface of the substrate to provide the surface of the substrate with water repellency.

A contact angle of the substrate that has been brought into contact with the surface treatment agent with respect to water is preferably 50° or more, more preferably 60° or more, and further preferably 70° or more from the viewpoint of water repellency. The upper limit of the contact angle with respect to water is not particularly limited and may be, for example, 120° or less.

### (Cleaning of Substrate Surface)

As the cleaning treatment of the substrate surface including an organic pattern or an inorganic pattern with a cleaning liquid, conventionally used cleaning liquid for cleaning treatment of an organic pattern or an inorganic pattern can be employed as it is. Examples of the cleaning liquid used for the organic pattern include water, rinse liquid including an active agent, and the like. Examples of the cleaning liquid used for the inorganic pattern include SPM (sulfuric acid-hydrogen peroxide solution), APM (ammonia-hydrogen peroxide solution), and the like.

The following is a reason why pattern collapse of an organic pattern or an inorganic pattern of a substrate surface can be prevented by the above method in cleaning of the substrate surface.

After the inorganic pattern is formed on the substrate surface, the surface of the pattern is generally cleaned with a cleaning liquid such as SPM or APM. It is general that also after the organic pattern is formed on the surface of the substrate, the developing residue and the adhering developing agent are removed by cleaning with a cleaning liquid such as water or an active rinse. Before cleaning the organic pattern or the inorganic pattern, a pattern surface is treated with the surface treatment agent to provide the surface of the pattern with water repellency.

Herein, as described above, the force F acting between the organic pattern and the inorganic pattern during cleaning is represented by the following formula (a). Herein, y represents the surface tension of the cleaning liquid, 0 represents the contact angle of the cleaning liquid, A represents the aspect ratio of the pattern, and D represents the distance between the pattern side walls. F=2γ·cos θ·A/D (a)

Therefore, if the surface of the pattern can be provided with water repellency, and the contact angle of the cleaning liquid can be increased (the cos θ can be reduced), the force acting between the patterns can be reduced during subsequent cleaning, and the pattern collapse can be prevented.

The surface treatment is carried out by immersing a substrate, on which an inorganic pattern or a resin pattern is formed, in a surface treatment agent, or by applying or spraying a surface treatment agent onto an inorganic pattern or a resin pattern. The surface treatment time is preferably within the preferred range described above for the contact time. Furthermore, the contact angle of water after the surface treatment on the pattern surface is preferably in the same range as the contact angle of the substrate with respect to the water after contact of the surface treatment agent.

Note here that from the viewpoint of throughput, it is preferable that the contact between the substrate and the surface treatment agent and the cleaning treatment are continuous. Therefore, it is preferable that the surface treatment agent has excellent replaceability with the cleaning liquid.

As described above, the present inventors provide the following [1] to [6].

[1] A surface treatment agent for use in treating a surface of a substrate including a pattern,
the surface treatment agent including a reactive silane compound, and a solvent,
the reactive silane compound including a compound represented by the following formula (1):

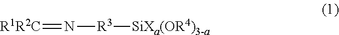

(In the formula (1), R¹ and R² are each independently a monovalent hydrocarbon group having 1 or more and 15 or less carbon atoms, and optionally having a substituent, or a hydrogen atom, R¹ and R² are not simultaneously a hydrogen atom, R¹ and R² are optionally bonded to each other to form a hydrocarbon ring, a total number of carbon atoms of R¹ and R² is 2 or more and 20 or less, R³ is an alkylene group having 1 or more and 5 or less carbon atoms, R⁴ is an alkyl group having 1 or more and 4 or less carbon atoms, or a hydrogen atom, X is a hydrocarbon group having 1 or more and 6 or less carbon atoms, a is an integer of 0 or more and 2 or less), and the solvent including water.

[2] The surface treatment agent described in [1], wherein R¹ is the hydrocarbon group, and R² is a hydrogen atom.

[3] The surface treatment agent described in [1] or [2], wherein a is 0.

[4] A silicon compound represented by the following formula (2):

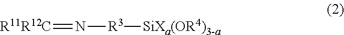

(In the formula (2), R¹¹ and R¹² are each independently a monovalent hydrocarbon group having 1 or more and 15 or less carbon atoms, optionally having a substituent, or a hydrogen atom, R¹¹ and R¹² are not simultaneously a hydrogen atom, R¹¹ and R¹² are optionally bonded to each other to form a hydrocarbon ring, a total number of carbon atoms of R¹¹ and R¹² is 2 or more and 20 or less, R³ is an alkylene group having 1 or more and 5 or less carbon atoms, R⁴ is an alkyl group having 1 or more and 4 or less carbon atoms, or a hydrogen atom, X is a hydrocarbon group having 1 or more and 6 or less carbon atoms, a is an integer of 0 or more and 2 or less, and when one of R¹¹ and R¹² is an n-propyl group, an isopropyl group, or a tert-butyl group, and the other of R¹¹ and R¹² is not a hydrogen atom).

[5] A method for suppressing pattern collapse in a substrate including a pattern when the surface of the substrate is cleaned with a cleaning liquid, the method including bringing a surface treatment agent described in one of [1] to [3] into contact with the surface of the substrate.

[6] The method described in [5], wherein at least a part of a surface to be surface-treated of the substrate includes one or more kinds selected from silicon, silicon dioxide, and silicon nitride.

### EXAMPLES

Hereinafter, the present invention is specifically described with reference to Examples. The present invention is not limited to these Examples.

### [Synthesis of Silicon Compound]

The following compound a to compound i corresponding to the silicon compounds represented by the formula (1) described above were prepared by the following method.

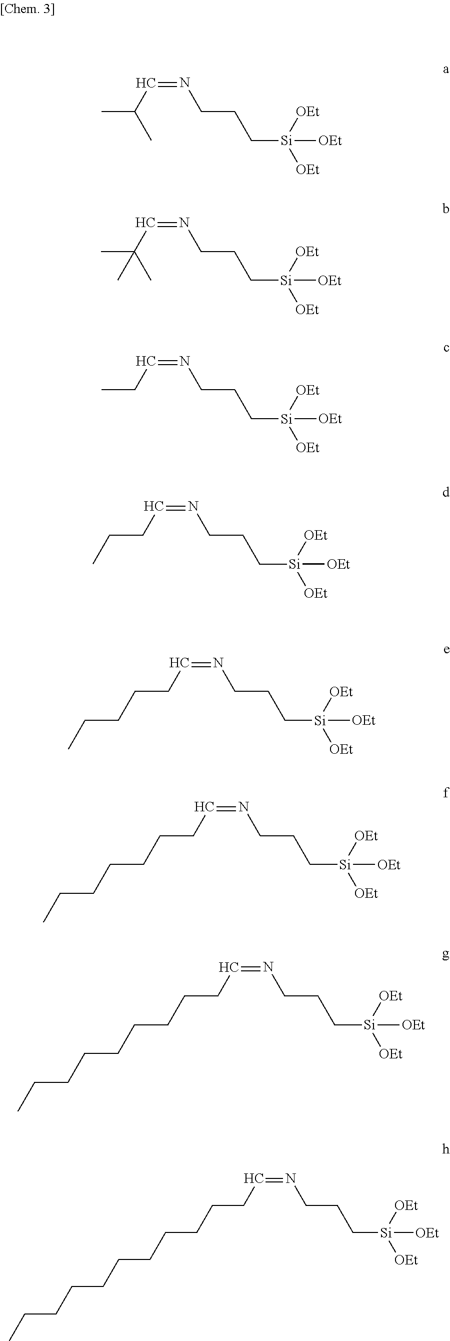

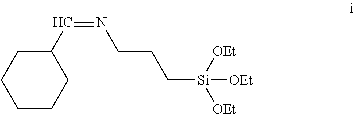 [SMILES: CCO[Si](CCC/N=C\C1CCCCC1)(OCC)OCC]

Firstly, 6.34 g of ethyl acetate was added to a 100-mL beaker. Then, 1.77 g (8 mmol) of 3-aminopropyltriethoxysilane (APTES) and 8 mmol of aldehyde were added to the beaker. The following aldehydes were used in the preparation of compound a to compound i.
Compound a: 2-methylpropanal
Compound b: 2,2-dimethylpropanal
Compound c: propanal
Compound d: butanal
Compound e: hexanal
Compound f: octanal
Compound g: decanal
Compound h: dodecanal
Compound i: cyclohexylmethanal

Thereafter, the mixture in the beaker was stirred at 25° C. and at 300 rpm for 1 hour. Then, 50 g of ethyl acetate was added to the beaker. The mixture in the beaker was cleaned three times with 50 g of deionized water, then volatile matter of ethyl acetate was distilled off under reduced pressure to dry an ethyl acetate solution including a product. Accordingly, the products (compound a to compound i) were obtained. The yields of the compound a to compound i were calculated based on the weights of the obtained products. The yields of the compound a to compound i are shown below. Furthermore, when infrared absorption spectrum obtained by Fourier transform infrared spectroscopy (FT-IR) for each of the obtained products was observed, a peak (1600 cm⁻¹) originating in an APTES-derived amino group (—NH₂) and a peak (1730 cm⁻¹) originating in an aldehyde-derived aldehyde group (—CHO) disappeared, and an absorption peak (1670 cm⁻¹) originating in an imino group (C═N) was observed. This shows that each of the compound a to compound i obtained by the above method has a desired structure.

### —Yield of Each Compound

Compound a: 95%
Compound b: 98%
Compound c: 96%
Compound d: 96%
Compound e: 96%
Compound f: 95%
Compound g: 98%
Compound h: 97%
Compound i: 98%

### Examples 1 to 9, Comparative Example 1, and Comparative Example 2

### (Preparation of Surface Treatment Agent)

Surface treatment agents of Examples 1 to 9 were prepared by uniformly dissolving silicon compounds of the kinds described in Table 1 in deionized water. The concentration of the silicon compound in the surface treatment agent was 3% by mass with respect to the mass of the surface treatment agent.

### (Surface Treatment)

Using the surface treatment agents obtained in Examples 1 to 9, Comparative Example 1, and Comparative Example 2, surface treatment of a silicon substrate was carried out according to the following method. Specifically, firstly, the silicon substrate was immersed in hydrofluoric acid (HF:water=100:1 (mass ratio)) at 25° C. for 1 minute to remove a natural oxide film on the substrate surface. Then, the silicon substrate was cleaned with deionized water for 1 minute. The silicon substrate after cleaning was immersed in the surface treatment agent of each Example and each Comparative Example at 25° C. for 1 minute to carry out surface treatment of the silicon substrate. The surface-treated silicon substrate was cleaned with deionized water for 1 minute, and then the silicon substrate was dried by a nitrogen stream to obtain a surface-treated substrate.

### (Measurement of Contact Angle of Water)

A contact angle of water on each surface-treated silicon substrate was measured according to the following method. Specifically, the contact angle of water was measured using Dropmaster700 (manufactured by Kyowa Interface Science Co., Ltd.). A pure water droplet (2.0 μL) was dropped onto the surface of the silicon substrate, and the value of the contact angle two seconds after dropping was employed as the contact angle of water of the silicon substrate. The results are shown in Table 1.

TABLE 1

| | | Water contact |
|---|---|---|
| | Silicon compound | angle (°) |
| Example 1 | Compound a | 79.2 |
| Example 2 | Compound b | 84.4 |
| Example 3 | Compound c | 69.1 |
| Example 4 | Compound d | 81.8 |
| Example 5 | Compound e | 77.3 |
| Example 6 | Compound f | 84.3 |
| Example 7 | Compound g | 86.9 |
| Example 8 | Compound h | 89.1 |
| Example 9 | Compound i | 77.0 |
| Comparative | 3-aminopropyltriethoxysilane | 31.8 |
| Example 1 | | |
| Comparative | n-octyltriethoxysilane | 28.8 |
| Example 2 | | |

Table 1 shows that the surface of the silicon substrate is satisfactorily provided with liquid repellency by bringing the surface treatment agents of Examples, having a structure corresponding to the structure of the Formula (1) and containing the compound a to compound i as silicon compounds, into contact with the surface of the silicon substrate to carry out the surface treatment. Therefore, the surface of the substrate including a pattern is treated with the surface treatment agents of Examples, pattern collapse can be suppressed when the surface of the substrate is cleaned with a cleaning liquid from the above-mentioned reason.

What is claimed is:

1. A surface treatment agent for use in treating a surface of a substrate having a pattern,
the surface treatment agent comprising a reactive silane compound, and a solvent,
the reactive silane compound comprising a compound represented by the following formula (1): 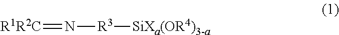
wherein in the formula (1), R¹ and R² are each independently a monovalent hydrocarbon group having 1 or more and 15 or less carbon atoms, optionally having a substituent, or a hydrogen atom, R¹ and R² are not simultaneously a hydrogen atom, R¹ and R² are optionally bonded to each other to form a hydrocarbon ring, a total number of carbon atoms of R¹ and R² is 2 or more and 20 or less, R³ is an alkylene group having 1 or more and 5 or less carbon atoms, R⁴ is an alkyl group having 1 or more and 4 or less carbon atoms, or a hydrogen atom, X is a hydrocarbon group having 1 or more and 6 or less carbon atoms, and a is an integer of 0 or more and 2 or less, and the solvent comprising water.

2. The surface treatment agent according to claim 1, wherein R¹ is the hydrocarbon group, and R² is a hydrogen atom.

3. The surface treatment agent according to claim 1, wherein a is 0.

4. A silicon compound represented by the following formula (2): 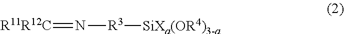
wherein in the formula (2), R¹¹ and R¹² are each independently a monovalent hydrocarbon group having 1 or more and 15 or less carbon atoms, optionally having a substituent, or a hydrogen atom, R¹¹ and R¹² are not simultaneously a hydrogen atom, R¹¹ and R¹² are optionally bonded to each other to form a hydrocarbon ring, a total number of carbon atoms of R¹¹ and R¹² is 2 or more and 20 or less, R³ is an alkylene group having 1 or more and 5 or less carbon atoms, R⁴ is an alkyl group having 1 or more and 4 or less carbon atoms, or a hydrogen atom, X is a hydrocarbon group having 1 or more and 6 or less carbon atoms, a is an integer of 0 or more and 2 or less, and
when one of R¹¹ and R¹² is an n-propyl group, an isopropyl group, or a tert-butyl group, the other of R¹¹ and R¹² is not a hydrogen atom.

5. A method for suppressing pattern collapse in a substrate having a pattern on a surface thereof when the surface of the substrate is cleaned with a cleaning liquid,
the method comprising bringing a surface treatment agent according to claim 1 into contact with the surface of the substrate.

6. The method according to claim 5, wherein at least a part of the surface to be surface-treated of the substrate comprises one or more kinds selected from silicon, silicon dioxide, and silicon nitride.
